(19) United States
(12) Patent Application Publication
(10) Pub. No.: US 2025/0344508 A1
(43) Pub. Date: Nov. 6, 2025

(54) ARRAY SUBSTRATE AND METHOD FOR PREPARING THE SAME AND DISPLAY PANEL

(71) Applicant: HKC CORPORATION LIMITED, Shenzhen (CN)

(72) Inventors: Chuan Wu, Shenzhen (CN); Haijiang Yuan, Shenzhen (CN)

(21) Appl. No.: 19/194,135

(22) Filed: Apr. 30, 2025

(30) Foreign Application Priority Data
May 6, 2024 (CN) 202410548579.9

(51) Int. Cl. H10D 86/40; H10D 86/01

(52) U.S. Cl. CPC H10D 86/441; H10D 86/021; H10D 86/451

(57) ABSTRACT

The array substrate includes a carrier substrate, a first signal line, a first insulating layer, a second signal line, a thin film transistor, a second insulating layer, and a bridging layer. The first insulating layer covers the first signal line and provides with a first through hole exposing the first signal line; the second signal line is located on a side of the first insulating layer; the second insulating layer covers the thin film transistor and the second signal line, and provides with a second through hole, a third through hole, and a connecting groove, and the connecting groove is in communication with the second through hole and the third through hole; the bridging layer is located in the connecting groove, connected to the first signal line through the second through hole and the first through hole, and connected to the second signal line through the third through hole.

### CROSS REFERENCE TO RELATED APPLICATION

Pursuant to 35 U.S.C. § 119 and the Paris Convention Treaty, the present application claims the benefit of Chinese Patent Application No. 202410548579.9 filed May 6, 2024, the contents of which are incorporated herein by reference.

### TECHNICAL FIELD

The present application relates to the technical field of display panels, and more particularly to an array substrate and a method for preparing the same and a display panel.

### BACKGROUND

Thin Film Transistor-Liquid Crystal Display (TFT-LCD) device has the advantages of good image quality, small size, light weight, low driving voltage, low power consumption, no radiation and relatively low manufacturing cost, and occupies a dominant position in the display field.

The array substrate is an important part of the thin film transistor liquid crystal display device, and the array substrate includes a carrier substrate and a circuit formed on a surface of the carrier substrate. The circuit structure on the surface of the array substrate is relatively fine. If the partial structure design of the array substrate is unreasonable, the circuit may have defects such as fractures at local positions, resulting in abnormal circuit structure and affecting the yield of the array substrate.

### SUMMARY

The embodiment of the present application provides an array substrate and a method for preparing the same and a display panel, which can improve the yield of the array substrate.

A first aspect of the embodiment of the present application provides an array substrate, and the array substrate includes:
a carrier substrate, provided with a display area and a non-display area;
a first signal line, located in the non-display area;
a first insulating layer, at least covering the first signal line and provided with a first through hole exposing the first signal line;
a second signal line, located on a side of the first insulating layer away from the carrier substrate, in which an orthographic projection of the second signal line on the carrier substrate partially overlaps with an orthographic projection of the first signal line on the carrier substrate;
a thin film transistor, located in the display area, wherein a gate of the thin film transistor is connected to the second signal line;
a second insulating layer, covering the thin film transistor and the second signal line, providing with a second through hole, a third through hole and a connecting groove, in which the second through hole is connected to the first through hole, the third through hole exposes the second signal line, and the connecting groove is in communication with the second through hole and the third through hole; and
a bridging layer, at least located in the connecting groove, and connected to the first signal line through the second through hole and the first through hole, and connected to the second signal line through the third through hole.

In some examples, a thickness of the second insulating layer at a bottom of the connecting groove is greater than 0.

In some examples, the second insulating layer includes a first sub-insulating layer and a second sub-insulating layer, the first sub-insulating layer covers the second signal line, and the second sub-insulating layer is located on a side of the first sub-insulating layer away from the carrier substrate; and
the connecting groove penetrates through the second sub-insulating layer, and the bridging layer is located on a surface of the first sub-insulating layer away from the carrier substrate.

In some examples, a material of the first sub-insulating layer is different from a material of the second sub-insulating layer.

In some examples, the connecting groove penetrates through the second insulating layer, and a material of the first insulating layer is different from a material of the second insulating layer.

In some examples, the array substrate further includes a common electrode, wherein the common electrode is located on a side of the second insulating layer away from the carrier substrate, and the common electrode is arranged in a same layer as the bridging layer and is made of a same material.

In some examples, a side of the orthographic projection of the second signal line on the carrier substrate penetrates through an orthographic projection of the connecting groove on the carrier substrate.

In some examples, an orthographic projection of the connecting groove on the carrier substrate is located within the orthographic projection of the first signal line on the carrier substrate.

A second aspect of the embodiment of the present application provides a method for preparing an array substrate, which includes:
forming a first signal line, a first insulating layer, a second signal line and a thin film transistor on a surface of a carrier substrate; the carrier substrate is provided with a display area and a non-display area; the first signal line is located in the non-display area; the second signal line is located on a side of the first insulating layer away from the carrier substrate, and an orthographic projection of the second signal line on the carrier substrate partially overlaps with an orthographic projection of the first signal line on the carrier substrate; the thin film transistor is located in the display area, and a gate of the thin film transistor is connected to the second signal line;
forming a second insulating layer, wherein the second insulating layer covers the thin film transistor and the second signal line, provides with a second through hole, a third through hole and a connecting groove, the second through hole is connected to the first through hole, the third through hole exposes the second signal line, and the connecting groove is in communication with the second through hole and the third through hole; and
forming a bridging layer, the bridging layer is at least located in the connecting groove, and connected to the first signal line through the second through hole and the first through hole, and connected to the second signal line through the third through hole.

A third aspect of the embodiment of the present application provides a display panel, which includes a pairing substrate and the array substrate described in the first aspect, and the pairing substrate is arranged opposite to the array substrate.

In the first aspect of the embodiment of the present application, the bridging layer is arranged, the bridging layer is connected to the first signal line through the second through hole and the first through hole that are in communication with each other, and the bridging layer is connected to the second signal line through the third through hole, so that the electrical signal can be conducted from the first signal line to the second signal line through the bridging layer, or from the second signal line to the first signal line through the bridging layer. Since the second through hole and the third through hole are both located in the second insulating layer, and the second insulating layer is further provided with the connecting groove, the connecting groove connects the second through hole and the third through hole, and the bridging layer is located in the connecting groove, so that the height difference between the part of the bridging layer located between the second through hole and the third through hole and the part of the bridging layer located in the second through hole or the third through hole is relatively small. When preparing the bridging layer, the risk of breaking of the bridging layer is relatively small, which is conducive to improving the yield of the array substrate.

It can be understood that the beneficial effects of the second and third aspects mentioned above can be referred to the relevant description in the first aspect mentioned above, and which will not be repeated here.

### BRIEF DESCRIPTION OF THE DRAWINGS

In order to more clearly illustrate the technical solutions in the embodiments of the present application, the drawings required for use in the embodiments or prior art descriptions will be briefly introduced below. Obviously, the drawings described below are only some embodiments of the present application. For ordinary technicians in this field, other drawings can also be obtained based on these drawings without creative work.

FIG. 1 is a top schematic diagram of an array substrate provided by an example of the present application;

FIG. 2 is a cross-sectional schematic diagram of the array substrate in a non-display area shown in FIG. 1;

FIG. 3 is a cross-sectional schematic diagram of the array substrate in a display area shown in FIG. 1;

FIG. 4 is a cross-sectional schematic diagram of an array substrate in a non-display area provided in Embodiment 2 of the present application;

FIG. 5 is a cross-sectional schematic diagram of an array substrate in a display area provided in Embodiment 2 of the present application;

FIG. 6 is a partial structural schematic diagram of the array substrate shown in FIG. 4;

FIG. 7 is a cross-sectional schematic diagram of a non-display area of an array substrate provided in Embodiment 3 of the present application;

FIG. 8 is a cross-sectional schematic diagram of a non-display area of an array substrate provided in Embodiment 4 of the present application;

FIG. 9 is a partial top view of an array substrate provided in Embodiment 5 of the present application; and

FIG. 10 is a flow chart of a method for preparing an array substrate provided in Embodiment 6 of the present application.

### REFERENCE NUMERALS

10—carrier substrate; 11—first signal line; 40—bridging layer; 12—second signal line; 21—first insulating layer; 22—second insulating layer; 23—third insulating layer; 30—thin film transistor; 31—first electrode; 32—second electrode; 33—gate; 34—active layer; 41—pixel electrode; 42—common electrode; 10a—display area; 10b—non-display area; 21a—first through hole; 22a—second through hole; 22b—third through hole; and 22c—connecting groove.

### DESCRIPTION OF THE EMBODIMENTS

In the following description, for the purpose of explanation rather than limitation, specific details such as specific system structures and technologies are proposed to thoroughly understand the embodiments of the present application. However, it should be clear to those skilled in the art that the present application can also be implemented in other embodiments without these specific details. In other cases, detailed descriptions of well-known systems, devices, circuits, and methods are omitted to avoid unnecessary details that hinder the description of the present application.

It should also be understood that the term “and/or” used in the specification of the present application and the attached claims refers to any combination of one or more of the associated listed items and all possible combinations, including these combinations.

It should be noted that when an element is referred to as “fixed to” or “set on” another element, it can be directly on the other element or indirectly on the other element. When an element is referred to as “connected to” another element, it can be directly connected to the other element or indirectly connected to the other element.

It should be understood that the orientation or position relationship indicated by the terms “length”, “width”, “upper”, “lower”, “front”, “back”, “left”, “right”, “vertical”, “horizontal”, “top”, “bottom”, “inside”, “outside”, etc. is based on the orientation or position relationship shown in the drawings, which is only for the convenience of describing the present application and simplifying the description, rather than indicating or implying that the device or element referred to must have a specific orientation, be constructed and operated in a specific orientation, and therefore cannot be understood as a limitation on the present application.

In addition, in the description of the specification of the present application and the attached claims, the terms “first”, “second”, “third”, etc. are only used to distinguish the description, and cannot be understood as indicating or implying relative importance.

References to “one embodiment” or “some embodiments” described in the specification of the present application mean that one or more embodiments of the present application include specific features, structures or characteristics described in combination with the embodiment. Therefore, the statements “in one embodiment”, “in some embodiments”, “in other embodiments”, “in some other embodiments”, etc. that appear in different places in this specification do not necessarily refer to the same embodiment, but mean “one or more but not all embodiments”, unless otherwise specifically emphasized in other ways. The terms “include”, “comprise”, “have” and their variations all mean “including but not limited to”, unless otherwise specifically emphasized in other ways. “Multiple” means two or more.

### Embodiment 1

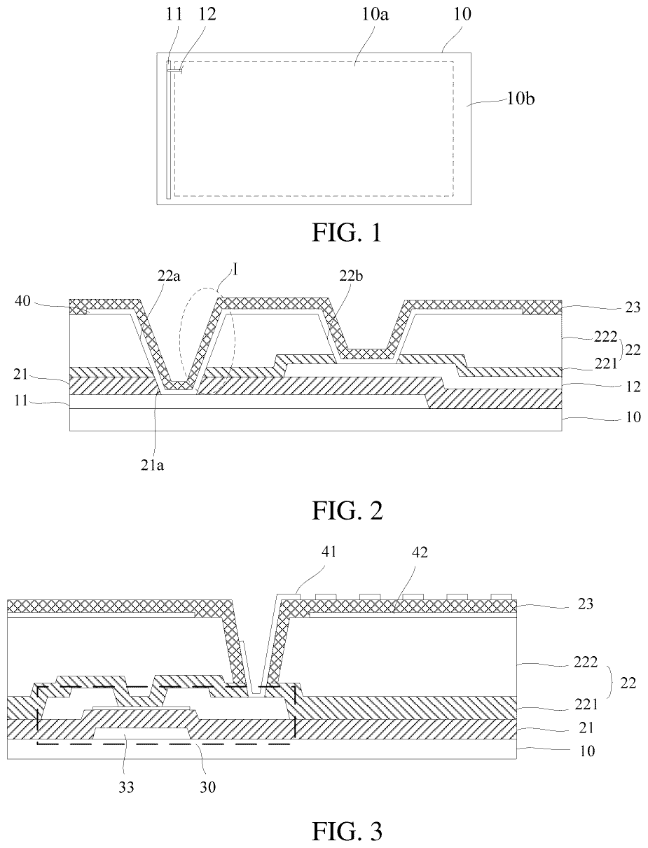

FIG. 1 is a top schematic diagram of an array substrate provided by an example of the present application. As shown in FIG. 1, the embodiment of the present application provides a first array substrate, which includes a carrier substrate 10 and a circuit formed on a side of the carrier substrate 10. The carrier substrate 10 is a carrier and provide with a display area 10a and a non-display area 10b. The display area 10a is generally located in the middle of the carrier substrate 10, and the non-display area 10b is generally located at the edge of the carrier substrate 10. A first signal line 11 is provided in the non-display area 10b of the carrier substrate 10, and a second signal line 12 is provided in the display area 10a.

FIG. 2 is a cross-sectional schematic diagram of the array substrate in the non-display area shown in FIG. 1. As shown in FIG. 2, a first insulating layer 21 is covered on the side of the first signal line 11 away from the carrier substrate 10, and the first insulating layer 21 is provided with a first through hole 21a exposing the first signal line 11. The second signal line 12 is located on the side of the first insulating layer 21 away from the carrier substrate 10. The second signal line 12 extends from the non-display area 10b to the display area 10a. A second insulating layer 22 is also covered on the side of the second signal line 12 away from the carrier substrate 10. The second insulating layer 22 is provided with a second through hole 22a and a third through hole 22b. The second through hole 22a is connected to the first through hole 21a, and the third through hole 22b exposes the second signal line 12.

The array substrate also includes a bridging layer 40 and a third insulating layer 23. The bridging layer 40 is located on the side of the second insulating layer 22 away from the carrier substrate 10. The bridging layer 40 is connected to the first signal line 11 through the second through hole 22a and the first through hole 21a, and the bridging layer 40 is connected to the second signal line 12 through the third through hole 22b. The third insulating layer 23 is located on the side of the second insulating layer 22 and the bridging layer 40 away from the carrier substrate 10.

In the embodiment of the present application, unless otherwise specified, connecting through through holes means achieving electrical connection, and the electrical connection is achieved by the structure located in the through hole. The structure used to achieve electrical connection in the through hole can be a part of any one of the two structures at both ends of the through hole, or it can be other structures other than the two structures at both ends of the through hole. For example, the bridging layer 40 is connected to the second signal line 12 through the third through hole 22b, which means that the bridging layer 40 and the second signal line 12 are electrically connected. The structure used to achieve electrical connection between the bridging layer 40 and the second signal line 12 in the third through hole 22b is the part of the bridging layer 40 located in the third through hole 22b.

If there is an abnormality in the bridging layer 40, such as a break, the first signal line 11 and the second signal line 12 will be disconnected, which affects the transmission of the signal, thereby affecting the function of the array substrate. As shown in FIG. 2, the bridging layer 40 includes a portion located in the first through hole 21a and the second through hole 22a, a portion located in the third through hole 22b, and a portion located between the second through hole 22a and the third through hole 22b. The total depth of the first through hole 21a and the second through hole 22a is relatively large, and the etching depth is large during preparation, which makes the morphology of the manufactured through holes often poor, for example, burrs are easily generated at the edge of the through holes. The poor morphology of the through holes causes the subsequent manufactured bridging layer 40 to be prone to breakage at a local position in the through hole, resulting in the high impedance of the portion of the bridging layer 40 located in the through hole, which is prone to heat and poor pressure resistance, and may even cause the through holes to burn, thereby affecting the yield of the array substrate.

In the embodiment of the present application, as shown in FIG. 2, the second insulating layer 22 includes a first sub-insulating layer 221 and a second sub-insulating layer 222 that are laminated, the first sub-insulating layer 221 covers the second signal line 12, and the second sub-insulating layer 222 is located on a side of the first sub-insulating layer 221 away from the carrier substrate 10.

FIG. 3 is a cross-sectional schematic diagram of the array substrate in the display area shown in FIG. 1. As shown in FIG. 3, a thin film transistor 30 is distributed in the display area 10a. The gate 33 of the thin film transistor 30 is connected to the second signal line 12. The first sub-insulating layer 221 covers the thin film transistor 30, and a pixel electrode 41 is provided on the side of the third insulating layer 23 away from the carrier substrate 10, and the pixel electrode 41 is connected to one of the source and drain of the thin film transistor 30 through a through hole.

In the embodiment of the present application, since the second insulating layer 22 includes two sub-layers, during the manufacturing process, etching can be performed in two steps, and each time one of the first sub-insulating layer 221 and the second sub-insulating layer 222 is etched, thereby the etching depth in a single etching process can be reduced, so as to improve the precision of the through hole, and make the manufactured second through hole 22a have a better morphology, thereby the possibility of the bridging layer 40 breaking in the second through hole 22a is reduced, and the impedance of the part of the bridging layer 40 located in the through hole is reduced, the heat generation is slowed down, the withstand voltage is improved, the possibility of the through hole being burned is reduced, and the yield of the array substrate is improved.

In some examples, the material of the first sub-insulating layer 221 is different from that of the second sub-insulating layer 222.

When etching the second sub-insulating layer 222, an etching solution that is easy to etch the second sub-insulating layer 222 but not easy to etch the first sub-insulating layer 221 can be used to reduce the impact of etching the second sub-insulating layer 222 on the first sub-insulating layer 221; when etching the first sub-insulating layer 221, an etching solution that is easy to etch the first sub-insulating layer 221 but not easy to etch the second sub-insulating layer 222 can be used to reduce the impact of etching the first sub-insulating layer 221 on the second sub-insulating layer 222. When etching the first sub-insulating layer 221, the second sub-insulating layer 222 can also be used as a mask to simplify the process.

### Embodiment 2

The embodiment of the present application provides a second array substrate, which includes a carrier substrate 10 and a circuit located on the surface of the carrier substrate 10.

After the array substrate is made into a display panel, the central area of the carrier substrate 10 corresponds to the area of the display screen, which is usually called the display area 10a, and the area outside the display area 10a is usually called the non-display area 10b, and the non-display area 10b is usually arranged around the display area 10a.

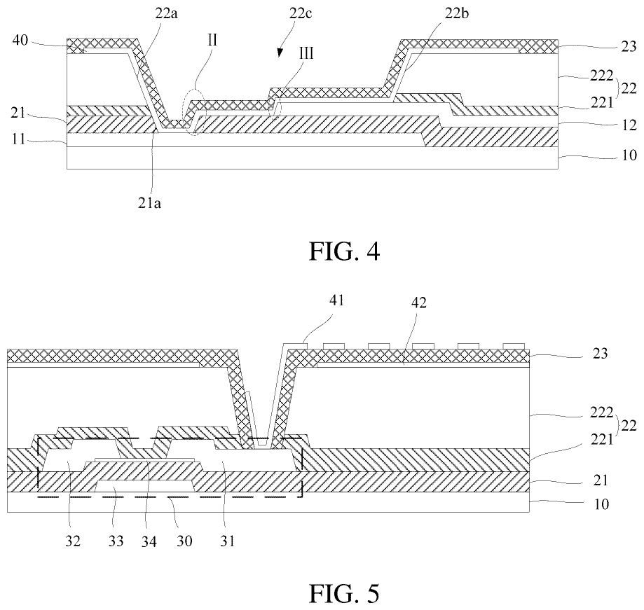

FIG. 4 is a cross-sectional schematic diagram of an array substrate in the non-display area provided in Embodiment 2 of the present application, and FIG. 5 is a cross-sectional schematic diagram of an array substrate in the display area provided in Embodiment 2 of the present application. As shown in FIGS. 4 and 5, the circuit structure in the array substrate includes a first signal line 11, a first insulating layer 21, a second signal line 12, a thin film transistor 30, a second insulating layer 22, and a bridging layer 40.

The first signal line 11 is located in the non-display area 10b. The first insulating layer 21 at least covers the first signal line 11, and the first insulating layer 21 is also provided with a first through hole 21a that exposes the first signal line 11. The second signal line 12 is located on the side of the first insulating layer 21 away from the carrier substrate 10, and the orthographic projection of the second signal line 12 on the carrier substrate 10 partially overlaps with the orthographic projection of the first signal line 11 on the carrier substrate 10.

The thin film transistor 30 is located in the display area 10a, and the thin film transistor 30 is provided with a gate 33, a first electrode 31, and a second electrode 32. The first electrode 31 is one of the source and the drain, and the second electrode 32 is the other of the source and the drain. The gate 33 of the thin film transistor 30 is connected to the second signal line 12.

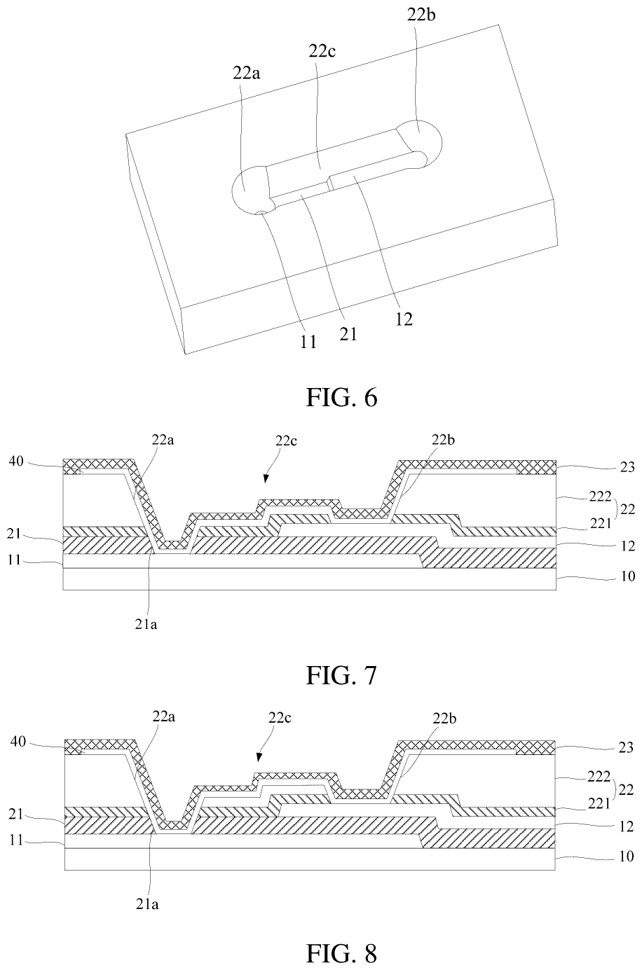

The second insulating layer 22 covers the thin film transistor 30 and the second signal line 12. FIG. 6 is a schematic diagram of the partial structure of the array substrate shown in FIG. 4. At least the bridging layer 40 is omitted in FIG. 6. As shown in FIG. 6, the second insulating layer 22 is provided with a second through hole 22a, a third through hole 22b, and a connecting groove 22c. The second through hole 22a is connected to the first through hole 21a, the third through hole 22b exposes the second signal line 12, and the connecting groove 22c is in communication with the second through hole 22a and the third through hole 22b. The bridging layer 40 is at least located in the connecting groove 22c. The bridging layer 40 is connected to the first signal line 11 through the second through hole 22a and the first through hole 21a, and the bridging layer 40 is also connected to the second signal line 12 through the third through hole 22b.

In the embodiment of the present application, by providing the bridging layer 40, the bridging layer 40 is connected to the first signal line 11 through the second through hole 22a and the first through hole 21a that are in communication with each other, and the bridging layer 40 is connected to the second signal line 12 through the third through hole 22b, so that the electrical signal can be transmitted from the first signal line 11 to the second signal line 12 through the bridging layer 40, or from the second signal line 12 to the first signal line 11 through the bridging layer 40. Since the second through hole 22a and the third through hole 22b are both located in the second insulating layer 22, and the second insulating layer 22 is further provided with a connecting groove 22c, the connecting groove 22c is in communication with the second through hole 22a and the third through hole 22b, and the bridging layer 40 is located in the connecting groove 22c, this makes the height difference between the portion of the bridging layer 40 located between the second through hole 22a and the third through hole 22b and the portion located in the second through hole 22a or the third through hole 22b relatively small. When preparing the bridging layer 40, the risk of breaking of the bridging layer 40 is relatively small, which is beneficial to improving the yield of the array substrate.

Comparing the positions shown in the elliptical dotted frame II in FIG. 4 and the elliptical dotted frame I in FIG. 2, after the connecting groove 22c is arranged, the height of the side wall of the second through hole 22a close to the third through hole 22b is reduced, the possibility of the bridging layer 40 breaking at the position shown in the elliptical dotted frame II is reduced. In addition, the length of the conduction path between the second through hole 22a and the third through hole 22b is shortened, the impedance is reduced, the heat generation at the second through hole 22a is reduced, the pressure resistance of the second through hole 22a is improved, the possibility of burning at the second through hole 22a is reduced, and the yield of the array substrate is further improved.

The circuit on the surface of the carrier substrate 10 generally includes a pixel circuit located in the display area 10a and a drive circuit located in the non-display area 10b. The drive circuit of the non-display area 10b may include, for example, a Gate Driver On Array (GOA) circuit. In the embodiment of the present application, the first signal line 11 may be a signal line in the gate driver on array circuit. The thin film transistor 30 may be a thin film transistor in the pixel circuit. The first signal line 11 is connected to the gate 33 of the thin film transistor 30 through the second signal line 12 to control the operation of the pixel circuit.

As an example, the first signal line 11 and the gate 33 of the thin film transistor 30 are arranged in the same layer and made of the same material. Since the first signal line 11 and the gate 33 of the thin film transistor 30 are arranged in the same layer and made of the same material, that is, the first signal line 11 and the gate 33 of the thin film transistor 30 can be formed by the same patterning process to achieve the purpose of saving process. Exemplarily, the first signal line 11 can be a single-layer structure made of metal material, such as a single-layer structure formed by metal copper Cu, or a multi-layer structure made of metal material, such as Al/Mo/MTD material, that is, a multi-layer structure of aluminum layer, molybdenum layer, molybdenum nickel titanium alloy layer.

The first insulating layer 21 can be located in the display area 10a and the non-display area 10b. Exemplarily, the first insulating layer 21 can be a gate insulating layer. The first insulating layer 21 can be made of an inorganic non-metallic material, for example, the first insulating layer 21 can include at least one of a silicon nitride layer and a silicon oxide layer. Exemplarily, the first insulating layer 21 includes a SiNx layer and a SiOx layer stacked on the side of the SiNx layer away from the carrier substrate 10.

The active layer 34 of the thin film transistor 30 is located on the side of the first insulating layer 21 away from the carrier substrate 10. Exemplarily, the thin film transistor 30 can be an oxide thin film transistor, and the active layer 34 can be a metal oxide semiconductor layer. In some examples, the thin film transistor 30 can also be a polycrystalline silicon thin film transistor, an amorphous silicon thin film transistor, or other thin film transistors.

The first electrode 31 and the second electrode 32 of the thin film transistor 30 are located on the side of the first insulating layer 21 away from the carrier substrate 10. At least two of the first electrode 31, the second electrode 32, and the second signal line 12 of the thin film transistor 30 can be arranged in the same layer and made of the same material. For example, in an embodiment of the present application, the first electrode 31, the second electrode 32, and the second signal line 12 of the thin film transistor 30 are arranged in the same layer and made of the same material, that is, the first electrode 31, the second electrode 32, and the second signal line 12 of the thin film transistor 30 can be formed by the same patterning process to achieve the purpose of saving process. Exemplarily, the second signal line 12 may be a single-layer structure made of a metal material, such as a single-layer structure formed of metal copper Cu, or a multi-layer structure made of a metal material, such as Al/Mo/MTD material, i.e., a multi-layer structure of an aluminum layer, a molybdenum layer, and a molybdenum nickel-titanium alloy layer.

The first insulating layer 21 may also provide with a through hole in the display area 10a, and the second signal line 12 is connected to the gate of the thin film transistor 30 through the through hole. For example, a gate line may also be provided in the display area 10a, the gate line is connected to the gate 33 of the thin film transistor 30, and the second signal line 12 is connected to the gate line through a through hole to achieve electrical connection between the second signal line 12 and the gate 33 of the thin film transistor 30.

The second insulating layer 22 may be located in the display area 10a and the non-display area 10b of the carrier substrate 10, covering the second signal line 12 and the thin film transistor 30. Exemplarily, the first sub-insulating layer 221 may be a passivationlayer (PVX), and the first sub-insulating layer 221 may be made of an inorganic non-metallic material, for example, the first sub-insulating layer 221 may include at least one of a silicon nitride layer and a silicon oxide layer. Exemplarily, the first sub-insulating layer 221 includes a SiOx layer and a SiNx layer laminated on a side of the SiOx layer away from the carrier substrate 10.

The second sub-insulating layer 222 may be located in the display area 10a and the non-display area 10b of the carrier substrate 10, and the second sub-insulating layer 222 covers the side of the first sub-insulating layer 221 away from the carrier substrate 10.

The second sub-insulating layer 222 can be made of inorganic non-metallic materials. For example, the second sub-insulating layer 222 can be a resin layer, a photoresist layer, or an acrylic layer. Exemplarily, the second sub-insulating layer 222 can be a perfluoroalkoxy resin PFA.

Optionally, the thickness of the second sub-insulating layer 222 is 1.5 μm-3 μm. The thickness of the second sub-insulating layer 222 is set relatively thick to form a relatively flat surface, so that the film layer formed subsequently is relatively flat.

In some examples, the first sub-insulating layer 221 and the second sub-insulating layer 222 are made of different materials.

Since the first sub-insulating layer 221 and the second sub-insulating layer 222 are made of different materials, when etching the second sub-insulating layer 222, an etching solution that is easy to etch the second sub-insulating layer 222 but not easy to etch the first sub-insulating layer 221 can be used to reduce the impact of etching the second sub-insulating layer 222 on the first sub-insulating layer 221.

As shown in FIG. 5, the array substrate further includes a common electrode 42, which is located on the side of the second insulating layer 22 away from the carrier substrate 10. The common electrode 42 is arranged in the same layer as the bridging layer 40 and is made of the same material.

Since the bridging layer 40 and the common electrode 42 are arranged in the same layer and are made of the same material, that is, the bridging layer 40 and the common electrode 42 can be formed by the same patterning process to achieve the purpose of saving process.

Exemplarily, both the common electrode 42 and the bridging layer 40 can be made of ITO material.

In the embodiment of the present application, the thickness of the second insulating layer 22 at the bottom of the connecting groove 22c is 0, that is, the connecting groove 22c penetrates through the second insulating layer 22, exposing the second signal line 12 and the first insulating layer 21. At the bottom of the connecting groove 22c, the bridging layer 40 directly covers the surface of the first insulating layer 21 and the second signal line 12. The height difference between the portion of the bridging layer 40 located in the first through hole 21a and the portion located in the connecting groove 22c is only the thickness of the first insulating layer 21, and the height difference is relatively small, which greatly reduces the possibility of the bridging layer 40 being broken from the bottom of the first through hole 21a to the bottom of the connecting groove 22c.

In the embodiment of the present application, the material of the first insulating layer 21 is different from the material of the second insulating layer 22. The material of the first insulating layer 21 is different from the material of the second insulating layer 22, which may include: the material of the first insulating layer 21 being different from the first sub-insulating layer 221; the material of the first insulating layer 21 being different from the first sub-insulating layer 221 and the second sub-insulating layer 222.

This allows the etching solution that is easy to etch the second insulating layer 22 but not easy to etch the first insulating layer 21 to avoid the etching solution from corroding the first insulating layer 21 at the bottom of the connecting groove 22c when etching the second insulating layer 22 to form the connecting groove 22c penetrating through the second insulating layer 22.

In other examples, if the second insulating layer 22 is a single-layer structure, the material of the first insulating layer 21 may also be different from that of the second insulating layer 22, so as to facilitate etching to form the connecting groove 22c and prevent the etching solution from corroding the first insulating layer 21 at the bottom of the connecting groove 22c.

### Embodiment 3

The present application provides a third array substrate, and FIG. 7 is a cross-sectional schematic diagram of a non-display area of an array substrate provided in Embodiment 3 of the present application. As shown in FIG. 7, compared with the array substrate shown in FIG. 4, in the array substrate shown in FIG. 7, the connecting groove 22c penetrates through the second sub-insulating layer 222, and the bridging layer 40 is located on the surface of the first sub-insulating layer 221 away from the carrier substrate 10.

For the example shown in FIG. 4, in the connecting groove 22c, a portion of the bridging layer 40 is located on the surface of the first insulating layer 21, and another portion of the bridging layer 40 is located on the surface of the second signal line 12. Since the second signal line 12 protrudes from the surface of the first insulating layer 21, the bottom of the connecting groove 22c is not flat. The portion of the bridging layer 40 located on the surface of the first insulating layer 21 and the portion of the bridging layer 40 located on the surface of the second signal line 12 are connected at the position shown in the elliptical dotted frame III in FIG. 4. As a result, the bridging layer 40 is more likely to break at the connection during the manufacturing process.

In the example shown in FIG. 7, since the connecting groove 22c does not penetrate through the second insulating layer 22, the surface of the first insulating layer 21 and the surface of the second signal line 12 are also covered with the first sub-insulating layer 221 between the second through hole 22a and the third through hole 22b, which makes the bottom of the connecting groove 22c relatively flat, the shape mutation of the bridging layer 40, and the possibility of the bridging layer 40 breaking at the shape mutation are reduced.

For the example shown in FIG. 7, the first sub-insulating layer 221 and the second sub-insulating layer 222 are made of different materials. When forming the connecting groove 22c, an etching solution that is easy to etch the second sub-insulating layer 222 but not easy to etch the first sub-insulating layer 221 can be used, so that the second sub-insulating layer 222 can be easily etched through to form a connecting groove 22c that penetrates through the second sub-insulating layer 222.

### Embodiment 4

The embodiment of the present application provides a fourth array substrate, and FIG. 8 is a cross-sectional schematic diagram of a non-display area of an array substrate provided in Embodiment 4 of the present application. As shown in FIG. 8, compared with the array substrate shown in FIG. 7, in the array substrate, the connecting groove 22c does not penetrate through the second sub-insulating layer 222.

Compared with the example shown in FIG. 7, in the array substrate shown in FIG. 8, the thickness of the second insulating layer 22 at the bottom of the connecting groove 22c is greater, which makes the bottom of the connecting groove 22c flatter, and the portion of the bridging layer 40 located at the bottom of the connecting groove 22c is flatter, and the risk of breaking of the bridging layer 40 is further reduced.

For the examples shown in FIG. 7 and FIG. 8, the thickness of the second insulating layer 22 at the bottom of the connecting groove 22c is greater than 0, so as to improve the flatness of the bottom of the connecting groove 22c and reduce the risk of breaking of the bridging layer 40. The greater the thickness of the second insulating layer 22 at the bottom of the connecting groove 22c, the flatter the bottom of the connecting groove 22c, and the less likely the bridging layer 40 will break at the bottom of the groove. However, the greater the thickness of the second insulating layer 22 at the bottom of the connecting groove 22c, the greater the risk of breaking of the bridging layer 40 at the portion of the hole wall of the first through hole 21a or the second through hole 22a. When designing an array substrate, the thickness of the second insulating layer 22 at the bottom of the connecting groove 22c can be simulated or tested to reduce the possibility of breaking of the bridging layer 40 to the required range.

### Embodiment 5

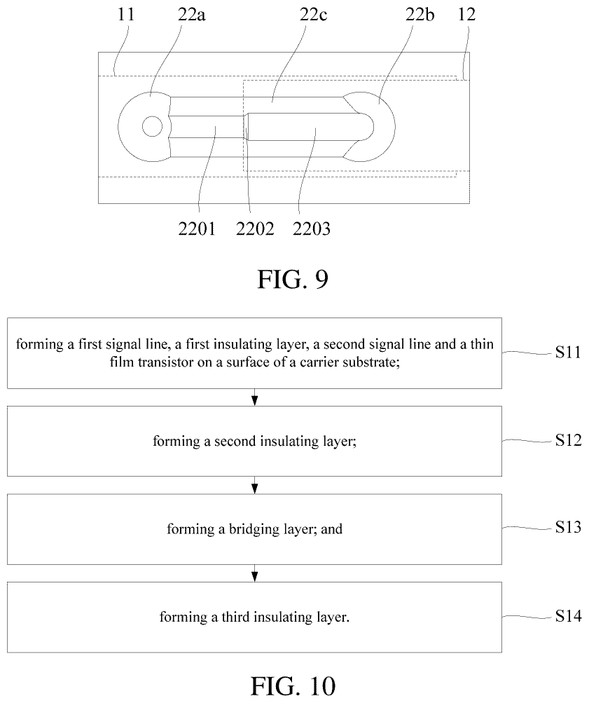

The present application embodiment provides a fifth array substrate, and FIG. 9 is a partial top schematic diagram of an array substrate provided in Embodiment 5 of the present application. As shown in FIG. 9, an edge of the orthographic projection of the second signal line 12 on the carrier substrate 10 penetrates through the orthographic projection of the connecting groove 22c on the carrier substrate 10.

In the embodiment of the present application, the bottom of the connecting groove 22c includes a first portion 2201, a second portion 2202 and a third portion 2203. The first portion 2201 is located close to the second through hole 22a, the third portion 2203 is located close to the third through hole 22b, and the second portion 2202 is located between the first portion 2201 and the second portion 2202. The orthographic projection of the first portion 2201 on the carrier substrate 10 is located outside the orthographic projection of the second signal line 12 on the carrier substrate 10, and the orthographic projection of the third portion 2203 on the carrier substrate 10 is located inside the orthographic projection of the second signal line 12 on the carrier substrate 10.

Since the second signal line 12 is located on the surface of the first insulating layer 21, the orthographic projection of the connecting groove 22c on the carrier substrate 10 and the orthographic projection of the second signal line 12 on the carrier substrate 10 have a partially overlapping area, so the bottom of the connecting groove 22c is not flat (see FIG. 6), and the distance from the first portion 2201 to the carrier substrate 10 is less than the distance from the third portion 2203 to the carrier substrate 10. The second portion 2202 connects the first portion 2201 and the third portion 2203, and the second portion 2202 is inclined relative to the surface of the carrier substrate 10. In the embodiment of the present application, since the orthographic projection of the second signal line 12 on the carrier substrate 10 has an edge that penetrates through the orthographic projection of the connecting groove 22c on the carrier substrate 10, only an inclined portion, i.e., a second portion 2202, is formed at the bottom of the connecting groove 22c, so that the bridging layer 40 is more easily formed at the bottom of the connecting groove 22c, and the possibility of the bridging layer 40 being broken is reduced.

As an example, in the orthographic projection of the second signal line 12 on the carrier substrate 10, an edge that penetrates through the orthographic projection of the connecting groove 22c on the carrier substrate 10 is perpendicular to the orthographic projection of the side wall of the connecting groove 22c on the carrier substrate 10, so that the width of the second portion 2202 can be reduced.

As shown in FIG. 9, the orthographic projection of the connecting groove 22c on the carrier substrate 10 is located within the orthographic projection of the first signal line 11 on the carrier substrate 10. Since the first insulating layer 21 covers the surface of the first signal line 11, the surface of the first insulating layer 21 away from the carrier substrate 10 is not flat. Assuming that a part of the orthographic projection of the connecting groove 22c on the carrier substrate 10 is located outside the orthographic projection of the first signal line 11 on the carrier substrate 10, this will cause a height difference between the part of the bottom of the connecting groove 22c located inside the first signal line 11 and the part located outside the first signal line 11, the flatness of the bottom of the connecting groove 22c is reduced, and the risk of breaking of the bridging layer 40 at the bottom of the connecting groove 22c is increased.

### Embodiment 6

FIG. 10 is a flow chart of a method for preparing an array substrate provided in Embodiment 6 of the present application. The method can be used to prepare any of the aforementioned array substrates. As shown in FIG. 10, the method includes:

In a step S11, a first signal line 11, a first insulating layer 21, a second signal line 12 and a thin film transistor 30 are formed on ta surface of the carrier substrate 10.

The carrier substrate 10 is provided with a display area 10a and a non-display area 10b, and the first signal line 11 is located in the non-display area 10b. The first insulating layer 21 at least covers the first signal line 11 and provides with a first through hole 21a exposing the first signal line 11. The second signal line 12 is located on the side of the first insulating layer 21 away from the carrier substrate 10, and the orthographic projection of the second signal line 12 on the carrier substrate 10 partially overlaps with the orthographic projection of the first signal line 11 on the carrier substrate 10. The thin film transistor 30 is located in the display area 10a, and the gate 33 of the thin film transistor 30 is connected to the second signal line 12.

In a step S12, a second insulating layer 22 is formed.

The second insulating layer 22 covers the thin film transistor 30 and the second signal line 12. The second insulating layer 22 is provided with a second through hole 22a, a third through hole 22b and a connecting groove 22c; the second through hole 22a is connected to the first through hole 21a, the third through hole 22b exposes the second signal line 12, and the connecting groove 22c is in communication with the second through hole 22a and the third through hole 22b.

In a step S13, a bridging layer 40 is formed.

The bridging layer 40 is at least located in the connecting groove 22c, and the bridging layer 40 is connected to the first signal line 11 through the second through hole 22a and the first through hole 21a, and the bridging layer 40 is connected to the second signal line 12 through the third through hole 22b.

In a step S14, a third insulating layer 23 is formed.

The third insulating layer 23 is located on the side of the second insulating layer 22 and the bridging layer 40 away from the carrier substrate 10.

By providing the bridging layer 40, the bridging layer 40 is connected to the first signal line 11 through the second through hole 22a and the first through hole 21a that are in communication with each other, and the bridging layer 40 is connected to the second signal line 12 through the third through hole 22b, so that the electrical signal can be transmitted from the first signal line 11 to the second signal line 12 through the bridging layer 40, or from the second signal line 12 to the first signal line 11 through the bridging layer 40. Since the second through hole 22a and the third through hole 22b are both located in the second insulating layer 22, and the second insulating layer 22 is further provided with a connecting groove 22c, the connecting groove 22c is in communication with the second through hole 22a and the third through hole 22b, and the bridging layer 40 is located in the connecting groove 22c, this makes the height difference between the portion of the bridging layer 40 located between the second through hole 22a and the third through hole 22b and the portion located in the second through hole 22a or the third through hole 22b relatively small. When preparing the bridging layer 40, the risk of breaking of the bridging layer 40 is relatively small, which is beneficial to improving the yield of the array substrate.

### Embodiment 7

Embodiment 7 of the present application provides a display panel, which may be, but is not limited to, a display panel in a mobile phone, a tablet computer, a laptop computer, a display, a smart wearable device, or a vehicle-mounted display device. The display panel includes a pairing substrate and an array substrate, and the array substrate may be any of the array substrates shown in the aforementioned embodiments.

### Embodiment 8

Embodiment 8 of the present application provides a display device, which includes the display panel of the aforementioned embodiment. The display device may be, but is not limited to, a mobile phone, a tablet computer, a laptop computer, a display, a smart wearable device, and a vehicle-mounted display device.

The above embodiments are only used to illustrate the technical solution of the present application, but not to limit it; although the present application is described in detail with reference to the above embodiments, ordinary technicians in this field should understand that: it is still possible to modify the technical solutions recorded in the above embodiments, or to replace some of the technical features therein by equivalent; and these modifications or replacements do not make the essence of the corresponding technical solutions deviate from the spirit and scope of the technical solutions of the embodiments of the present application, and should be included in the protection scope of the present application.

What is claimed is:

1. An array substrate, comprising:
a carrier substrate, provided with a display area and a non-display area;
a first signal line, located in the non-display area;
a first insulating layer, at least covering the first signal line and provided with a first through hole exposing the first signal line;
a second signal line, located on a side of the first insulating layer away from the carrier substrate, wherein an orthographic projection of the second signal line on the carrier substrate partially overlaps with an orthographic projection of the first signal line on the carrier substrate;
a thin film transistor, located in the display area, wherein a gate of the thin film transistor is connected to the second signal line;
a second insulating layer, covering the thin film transistor and the second signal line, providing with a second through hole, a third through hole and a connecting groove, wherein the second through hole is connected to the first through hole, the third through hole exposes the second signal line, and the connecting groove is in communication with the second through hole and the third through hole; and
a bridging layer, at least located in the connecting groove, and connected to the first signal line through the second through hole and the first through hole, and connected to the second signal line through the third through hole.

2. The array substrate according to claim 1, wherein a thickness of the second insulating layer at a bottom of the connecting groove is greater than 0.

3. The array substrate according to claim 2, wherein the second insulating layer comprises a first sub-insulating layer and a second sub-insulating layer, the first sub-insulating layer covers the second signal line, and the second sub-insulating layer is located on a side of the first sub-insulating layer away from the carrier substrate; and
the connecting groove penetrates through the second sub-insulating layer, and the bridging layer is located on a surface of the first sub-insulating layer away from the carrier substrate.

4. The array substrate according to claim 3, wherein a material of the first sub-insulating layer is different from a material of the second sub-insulating layer.

5. The array substrate according to claim 1, wherein the connecting groove penetrates through the second insulating layer, and a material of the first insulating layer is different from a material of the second insulating layer.

6. The array substrate according to claim 1, further comprising a common electrode, wherein the common electrode is located on a side of the second insulating layer away from the carrier substrate, and the common electrode is arranged in a same layer as the bridging layer and is made of a same material.

7. The array substrate according to claim 2, further comprising a common electrode, wherein the common electrode is located on a side of the second insulating layer away from the carrier substrate, and the common electrode is arranged in a same layer as the bridging layer and is made of a same material.

8. The array substrate according to claim 1, wherein a side of the orthographic projection of the second signal line on the carrier substrate penetrates through an orthographic projection of the connecting groove on the carrier substrate.

9. The array substrate according to claim 2, wherein a side of the orthographic projection of the second signal line on the carrier substrate penetrates through an orthographic projection of the connecting groove on the carrier substrate.

10. The array substrate according to claim 1, wherein an orthographic projection of the connecting groove on the carrier substrate is located within the orthographic projection of the first signal line on the carrier substrate.

11. The array substrate according to claim 2, wherein an orthographic projection of the connecting groove on the carrier substrate is located within the orthographic projection of the first signal line on the carrier substrate.

12. A method for preparing an array substrate, comprising:
forming a first signal line, a first insulating layer, a second signal line and a thin film transistor on a surface of a carrier substrate; wherein the carrier substrate is provided with a display area and a non-display area; the first signal line is located in the non-display area; the second signal line is located on a side of the first insulating layer away from the carrier substrate, and an orthographic projection of the second signal line on the carrier substrate partially overlaps with an orthographic projection of the first signal line on the carrier substrate; the thin film transistor is located in the display area, and a gate of the thin film transistor is connected to the second signal line;
forming a second insulating layer, wherein the second insulating layer covers the thin film transistor and the second signal line, provides with a second through hole, a third through hole and a connecting groove, wherein the second through hole is connected to the first through hole, the third through hole exposes the second signal line, and the connecting groove is in communication with the second through hole and the third through hole; and
forming a bridging layer, wherein the bridging layer is at least located in the connecting groove, and connected to the first signal line through the second through hole and the first through hole, and connected to the second signal line through the third through hole.

13. A display panel, comprising a pairing substrate and an array substrate; wherein the array substrate comprises:
a carrier substrate, provided with a display area and a non-display area;
a first signal line, located in the non-display area;
a first insulating layer, at least covering the first signal line and provided with a first through hole exposing the first signal line;
a second signal line, located on a side of the first insulating layer away from the carrier substrate, wherein an orthographic projection of the second signal line on the carrier substrate partially overlaps with an orthographic projection of the first signal line on the carrier substrate;
a thin film transistor, located in the display area, wherein a gate of the thin film transistor is connected to the second signal line;
a second insulating layer, covering the thin film transistor and the second signal line, providing with a second through hole, a third through hole and a connecting groove, wherein the second through hole is connected to the first through hole, the third through hole exposes the second signal line, and the connecting groove is in communication with the second through hole and the third through hole; and
a bridging layer, at least located in the connecting groove, and connected to the first signal line through the second through hole and the first through hole, and connected to the second signal line through the third through hole; and
wherein the pairing substrate is arranged opposite to the array substrate.

14. The display panel according to claim 13, wherein a thickness of the second insulating layer at a bottom of the connecting groove is greater than 0.

15. The display panel according to claim 14, wherein the second insulating layer comprises a first sub-insulating layer and a second sub-insulating layer, the first sub-insulating layer covers the second signal line, and the second sub-insulating layer is located on a side of the first sub-insulating layer away from the carrier substrate; and
the connecting groove penetrates through the second sub-insulating layer, and the bridging layer is located on a surface of the first sub-insulating layer away from the carrier substrate.

16. The display panel according to claim 15, wherein a material of the first sub-insulating layer is different from a material of the second sub-insulating layer.

17. The display panel according to claim 13, wherein the connecting groove penetrates through the second insulating layer, and a material of the first insulating layer is different from a material of the second insulating layer.

18. The display panel according to claim 13, further comprising a common electrode, wherein the common electrode is located on a side of the second insulating layer away from the carrier substrate, and the common electrode is arranged in a same layer as the bridging layer and is made of a same material.

19. The display panel according to claim 13, wherein a side of the orthographic projection of the second signal line on the carrier substrate penetrates through an orthographic projection of the connecting groove on the carrier substrate.

20. The display panel according to claim 13, wherein an orthographic projection of the connecting groove on the carrier substrate is located within the orthographic projection of the first signal line on the carrier substrate.
